(19) United States
(12) Patent Application Publication
(10) Pub. No.: US 2012/0223336 A1
(43) Pub. Date: Sep. 6, 2012

(54) SEMICONDUCTOR DEVICE

(75) Inventor: Shunsuke SAKAMOTO, Fukuoka (JP)

(73) Assignee: MITSUBISHI ELECTRIC CORPORATION, Chiyoda-ku (JP)

(21) Appl. No.: 13/302,490

(22) Filed: Nov. 22, 2011

(30) Foreign Application Priority Data
Mar. 3, 2011 (JP) 2011-046451

(51) Int. Cl. H01L 29/161; H01L 29/73

(52) U.S. Cl. 257/77; 257/587; 257/E29.082; 257/E29.183

(57) ABSTRACT

A semiconductor device includes a semiconductor substrate including a collector layer of a first conductivity type and a drift layer of a second conductivity type in contact with said collector layer, said drift layer receiving a supply of carriers from said collector layer. The semiconductor device further includes a lattice defect formed to penetrate through said semiconductor substrate and enclose a predetermined portion of said semiconductor substrate, a sense emitter electrode formed on the top surface of said predetermined portion, and a collector electrode formed on the bottom surface of said predetermined portion.

### BACKGROUND OF THE INVENTION

### Field of the Invention

The present invention relates to a semiconductor device including a power device and a sense device, wherein the current flowing in the sense device is small and proportional to the current in the power device.

### Background Art

Japanese Laid-Open Patent Publication No. 2010-199559 discloses a semiconductor device including a power device in which carriers are injected into the drift layer to modulate the conductivity of the layer. This semiconductor device also includes a sense device for protecting the power device from overcurrent or excessive current. The sense device is such that the current flowing therethrough is small and proportional to the current in the power device.

Incidentally, it is known practice to measure the VCE-IC characteristic (or collector-emitter saturation voltage characteristic) of the sense device in the course of the manufacture of the semiconductor device. The measurement results are fed forward to subsequent processes in order to correct or compensate for variations in the characteristics of the semiconductor device. It has been found in some cases, however, that when the collector-emitter saturation voltage characteristic of the sense device is measured, excess carriers are supplied to the drift layer, causing a snapback phenomenon. The snapback phenomenon prevents accurate measurement of the collector-emitter saturation voltage characteristic of the sense device.

### SUMMARY OF THE INVENTION

The present invention has been made to solve this problem. It is, therefore, an object of the present invention to provide a semiconductor device having a sense device whose collector-emitter saturation voltage characteristic can be accurately measured.

According to one aspect of the present invention, a semiconductor device includes a semiconductor substrate including a collector layer of a first conductivity type and a drift layer of a second conductivity type in contact with the collector layer, the drift layer receiving a supply of carriers from the collector layer, a lattice defect formed to penetrate through the semiconductor substrate and enclose a predetermined portion of the semiconductor substrate, a sense emitter electrode formed on the top surface of the predetermined portion, and a collector electrode formed on the bottom surface of the predetermined portion.

According to another aspect of the present invention, a semiconductor device includes a collector electrode, a collector layer of a first conductivity type in contact with the collector electrode, a buffer layer of a second conductivity type having a first portion and a second portion integrally formed with each other, the first portion being in contact with the collector electrode, the second portion being in contact with the collector layer, a drift layer of the second conductivity type in contact with the buffer layer, and a sense emitter electrode formed directly above the first portion.

According to another aspect of the present invention, a semiconductor device includes a semiconductor substrate including a collector layer of a first conductivity type and a drift layer of a second conductivity type in contact with the collector layer, the drift layer receiving a supply of carriers from the collector layer, an emitter electrode formed on the top surface of the semiconductor substrate, a sense emitter electrode formed on the top surface of the semiconductor substrate, the sense emitter electrode being smaller in area than the emitter electrode, a collector electrode formed on the bottom surface of the semiconductor substrate, and a sense collector electrode formed on the bottom surface of the semiconductor substrate, the sense collector electrode being smaller in area than the collector electrode.

Other and further objects, features and advantages of the invention will appear more fully from the following description.

### BRIEF DESCRIPTION OF THE DRAWINGS

FIG. 1 is a cross-sectional view of a semiconductor device in accordance with a first embodiment of the present invention;

FIG. 2 is a plan view showing the lattice defect shown in FIG. 1 and its surrounding regions;

FIG. 3 is a cross-sectional view showing the movement of holes in and around the lattice defect;

FIG. 4 is a diagram showing in solid line the VCE-IC characteristic of the sense device of the semiconductor device of the first embodiment;

FIG. 5 is a cross-sectional view of the sense device of a semiconductor device in accordance with a second embodiment of the present invention;

FIG. 6 is a diagram showing in solid line the VCE-IC characteristic of the sense device of the semiconductor device of the second embodiment; and

FIG. 7 is a cross-sectional view of a semiconductor device in accordance with a third embodiment of the present invention.

### DETAILED DESCRIPTION OF THE PREFERRED EMBODIMENTS

### First Embodiment

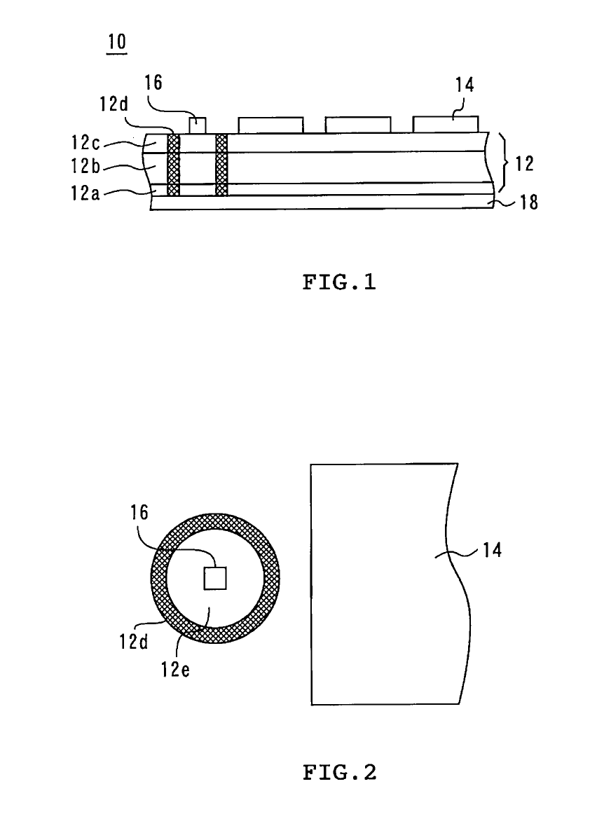

FIG. 1 is a cross-sectional view of a semiconductor device 10 in accordance with a first embodiment of the present invention. The semiconductor device 10 includes a semiconductor substrate 12 formed of silicon. The semiconductor substrate 12 includes a p-type collector layer 12a. An n-type drift layer 12b is formed in contact with the collector layer 12a. The conductivity of the drift layer 12b is modulated by carriers supplied from the collector layer 12a. An emitter layer 12c is formed in contact with the drift layer 12b.

A lattice defect 12d is formed to penetrate through the semiconductor substrate 12. This lattice defect 12d is formed by irradiating the semiconductor substrate 12 with an electron beam at 750 keV using a SUS mask.

An emitter electrode 14 is formed on the top surface of the semiconductor substrate 12. The emitter electrode 14 is the emitter electrode of the power device. In addition to the emitter electrode 14, a sense emitter electrode 16 is formed on the top surface of the semiconductor substrate 12. The sense emitter electrode 16 is smaller in area than the emitter electrode 14. On the other hand, a collector electrode 18 is formed on the bottom surface of the semiconductor substrate 12. The collector electrode 18 is formed to extend over the entire bottom surface of the semiconductor substrate 12.

FIG. 2 is a plan view showing the lattice defect 12d shown in FIG. 1 and its surrounding regions. The lattice defect 12d is formed to enclose a predetermined portion of the semiconductor substrate 12. This predetermined portion is referred to herein as the “sense substrate 12e.” The sense emitter electrode 16 is formed on the top surface of the sense substrate 12e (i.e. , the predetermined portion). Further, the collector electrode 18 extends over the bottom surface of the sense substrate 12e. The sense emitter electrode 16, the sense substrate 12e, and the portion of the collector electrode 18 under the sense substrate 12e together form a sense device. The sense device is formed in order to measure the VCE-IC characteristic (or collector-emitter saturation voltage characteristic) in the course of the manufacture of the semiconductor device. The VCE-IC characteristic thus measured in the course of the manufacture of the semiconductor device is fed forward to subsequent processes in order to correct or compensate for variations in the characteristics of the device.

It should be noted that generally the area of the sense emitter electrode is very small, approximately a few ten-thousandths of the area of the collector electrode. Therefore, when the VCE-IC characteristic of the sense device is measured, the sense device is deficient in electrons, which form the collector current. In other words, the drift layer under the sense emitter electrode has excess holes. As a result it has been found that the snapback phenomenon, which refers to the appearance of negative resistance, may occur when the VCE-IC characteristic of the sense device is measured by use of the sense emitter electrode and the collector electrode.

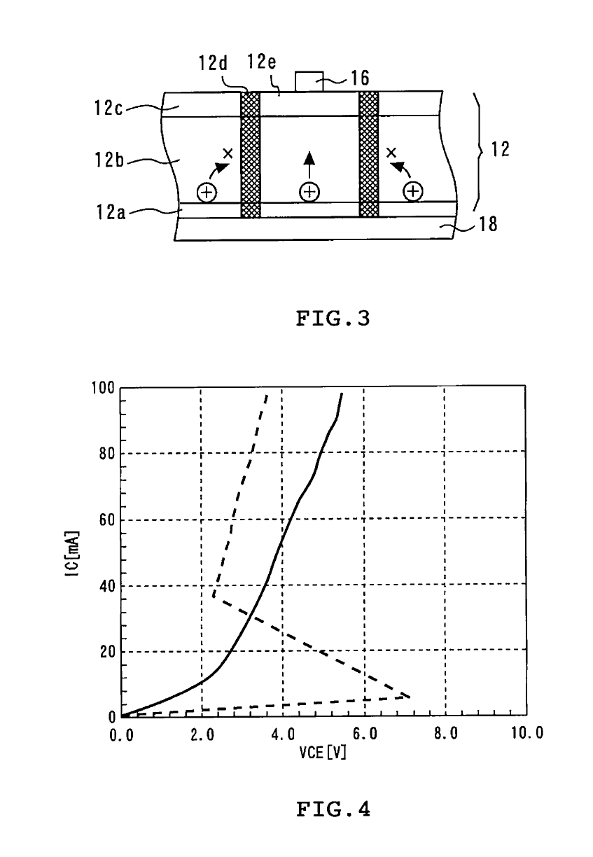

However, the construction of the semiconductor device 10 of the first embodiment prevents the snapback phenomenon from occurring when the VCE-IC characteristic is measured. Specifically, since the lattice defect 12d is formed to penetrate through the semiconductor substrate 12 and enclose the predetermined portion (i.e., the sense substrate 12e) of the substrate, holes do not concentrate into the drift layer 12b under the sense emitter electrode 16. The reason for this will be described with reference to FIG. 3. FIG. 3 is a cross-sectional view showing the movement of holes in and around the lattice defect 12d. As can be seen from this figure, the lattice defect 12d causes holes moving from outside of the sense substrate 12e toward the drift layer 12b of the sense substrate 12e to disappear. This is because the lattice defect 12d acts as a carrier recombination center.

Thus, excess holes are not supplied to the drift layer 12b of the sense substrate 12e, avoiding the snapback phenomenon. This makes it possible to adjust the conditions of subsequent processes so as to correct or compensate for variations in the characteristics of the semiconductor device.

FIG. 4 is a diagram showing in solid line the VCE-IC characteristic of the sense device of the semiconductor device 10 of the first embodiment. FIG. 4 also shows in dashed line the snapback phenomenon occurring in a semiconductor device without the lattice defect 12d. This figure indicates that the construction of the semiconductor device 10 of the first embodiment prevents the snapback phenomenon from occurring when the VCE-IC characteristic is measured.

Various alterations may be made to the semiconductor device 10 of the first embodiment. For example, an n-type buffer layer may be formed between the collector layer 12a and the drift layer 12b. In this structure the carrier concentration in the buffer layer may be increased to reduce the supply of holes to the drift layer and thereby prevent the snapback phenomenon. Or instead of increasing the carrier concentration in the buffer layer, the carrier concentration in the collector layer may be reduced to obtain the same effect.

Further in the semiconductor device of the first embodiment, the conductivity type of each layer may be reversed.

Although in the first embodiment the semiconductor substrate 12 is formed of silicon, it is to be understood that it may be formed of a wide bandgap semiconductor having a wider bandgap than silicon. Examples of wide bandgap semiconductors include silicon carbide, gallium nitride-based materials, and diamond.

### Second Embodiment

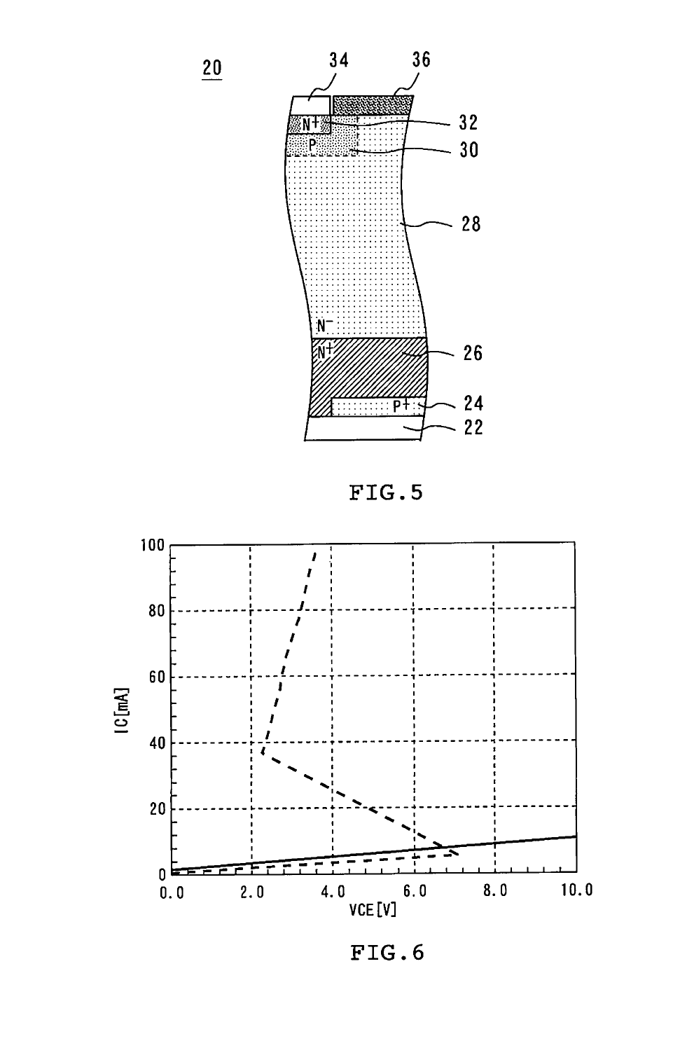

FIG. 5 is a cross-sectional view of the sense device of a semiconductor device 20 in accordance with a second embodiment of the present invention. The semiconductor device 20 includes a collector electrode 22. A p-type collector layer 24 is formed in contact with the collector electrode 22. Further, the semiconductor device 20 includes an n-type buffer layer 26 having a first portion in contact with the collector electrode 22 and a second portion in contact with the collector layer 24, these first and second portions being integrally formed with each other.

Further, an n-type drift layer 28 is formed in contact with the buffer layer 26. An emitter layer 32 is formed in the drift layer 28 with a p-type layer 30 interposed therebetween. A sense emitter electrode 34 is formed in contact with the emitter layer 32. The sense emitter electrode 34 is located directly above the first portion of the buffer layer 26. Further, a gate electrode 36 is formed in contact with the p-type layer 30.

Thus in the sense device of the semiconductor device 20 of the second embodiment, the first portion of the buffer layer 26 is directly connected to the collector electrode 22, thus forming a collector shorted structure. That is, the sense device of the semiconductor device 20 of the second embodiment has a vertical MOS structure.

FIG. 6 is a diagram showing in solid line the VCE-IC characteristic of the sense device of the semiconductor device 20 of the second embodiment. FIG. 6 also shows in dashed line the VCE-IC characteristic of a sense device undergoing the snapback phenomenon. Since the sense device of the semiconductor device 20 has a vertical MOS structure, the sense device does not undergo the snapback phenomenon associated with power devices, making it possible to reliably measure its VCE-IC characteristic. It should be noted that the semiconductor device of the second embodiment is susceptible of at least alterations which are the same as or correspond to those that can be made to the semiconductor device of the first embodiment.

### Third Embodiment

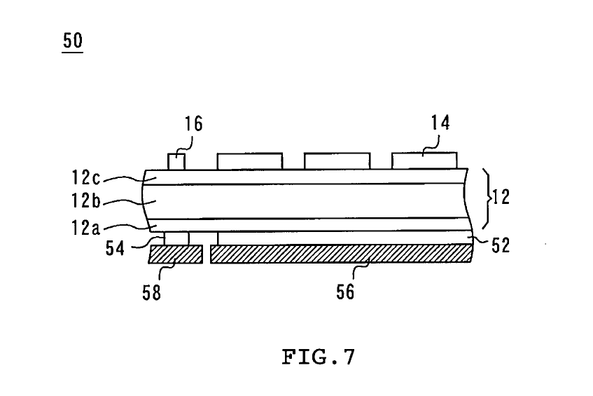

FIG. 7 is a cross-sectional view of a semiconductor device 50 in accordance with a third embodiment of the present invention. Components of the semiconductor device 50 which are identical to those of the first embodiment are denoted by the same reference numerals and will not be described herein.

The semiconductor device 50 includes a collector electrode 52 formed on the bottom surface of the semiconductor substrate 12. Further, a sense collector electrode 54 smaller in area than the collector electrode 52 is also formed on the bottom surface of the semiconductor substrate 12. The sense collector electrode 54 is located directly below the sense emitter electrode 16. It should be noted that the collector electrode 52 and the sense collector electrode 54 are not directly connected to each other; they are isolated from each other.

Since the semiconductor device 50 of the third embodiment includes the sense collector electrode 54 smaller in area than the collector electrode 52, the VCE-IC characteristic of the sense device can be measured by applying a voltage to the sense collector electrode 54 without applying the voltage to the collector electrode 52. Therefore, the supply of holes to the drift layer 12b can be reduced, as compared to when a voltage is applied to a collector electrode in contact with the entire collector layer 12a.

The measurement method will now be specifically described. The VCE-IC characteristic of the sense device of the semiconductor device 50 of the third embodiment is measured using the measuring stages 56 and 58 shown in FIG. 7. Specifically, the measuring stage 56 is brought into contact with the collector electrode 52, and the measuring stage 58 is brought into contact with the sense collector electrode 54. A voltage is then applied to only the sense collector electrode 54 to measure the VCE-IC characteristic of the sense device.

It should be noted that the semiconductor device of the present embodiment is susceptible of at least alterations which are the same as or correspond to those that can be made to the semiconductor device of the first embodiment.

Thus in accordance with the present invention there are provided semiconductor devices having a sense device in which the carrier supply to the drift layer is reduced, thereby allowing for accurate measurement of the collector-emitter saturation voltage characteristic.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2011-046451, filed on Mar. 3, 2011 including specification, claims, drawings and summary, on which the Convention priority of the present application is based, are incorporated herein by reference in its entirety.

What is claimed is:

1. A semiconductor device comprising:
a semiconductor substrate including a collector layer of a first conductivity type and a drift layer of a second conductivity type in contact with said collector layer, said drift layer receiving a supply of carriers from said collector layer;
a lattice defect formed to penetrate through said semiconductor substrate and enclose a predetermined portion of said semiconductor substrate;
a sense emitter electrode formed on the top surface of said predetermined portion; and
a collector electrode formed on the bottom surface of said predetermined portion.

2. A semiconductor device comprising:
a collector electrode;
a collector layer of a first conductivity type in contact with said collector electrode;
a buffer layer of a second conductivity type having a first portion and a second portion integrally formed with each other, said first portion being in contact with said collector electrode, said second portion being in contact with said collector layer;
a drift layer of said second conductivity type in contact with said buffer layer; and
a sense emitter electrode formed directly above said first portion.

3. A semiconductor device comprising:
a semiconductor substrate including a collector layer of a first conductivity type and a drift layer of a second conductivity type in contact with said collector layer, said drift layer receiving a supply of carriers from said collector layer;
an emitter electrode formed on the top surface of said semiconductor substrate;
a sense emitter electrode formed on said top surface of said semiconductor substrate, said sense emitter electrode being smaller in area than said emitter electrode;
a collector electrode formed on the bottom surface of said semiconductor substrate; and
a sense collector electrode formed on said bottom surface of said semiconductor substrate, said sense collector electrode being smaller in area than said collector electrode.

4. The semiconductor device according to claim 1, wherein said semiconductor substrate is formed of a wide bandgap semiconductor.

5. The semiconductor device according to claim 2, wherein said collector layer, said buffer layer, and said drift layer are formed of a wide bandgap semiconductor.

6. The semiconductor device according to claim 4, wherein said wide bandgap semiconductor is silicon carbide, gallium nitride-based material, or diamond.
